(19) United States
(12) Patent Application Publication
(10) Pub. No.: US 2026/0302101 A1
(43) Pub. Date: Oct. 1, 2026

(54) FLEXIBLE OR MOVEABLE SUBSTRATE WITH FORCE SENSING ARCHITECTURE

(71) Applicant: Logitech Europe S.A., Lausanne (CH)

(72) Inventors: Frédéric Alexis Guillaume de Goumoëns, Morges (CH); Léo Zeender, Lausanne (CH)

(21) Appl. No.: 19/093,961

(22) Filed: Mar. 28, 2025

(51) Int. Cl. H01H 13/70; G01L 1/12; H01H 13/04; H01H 13/10; H01H 13/14; H05K 1/18

(52) U.S. Cl. CPC H01H 13/7006; G01L 1/127; H01H 13/04; H01H 13/10; H01H 13/14; H05K 1/181; H05K 1/189; H05K 2201/10053; H05K 2201/10151

(57) ABSTRACT

A system for a keyed input device comprising a substrate, a keyswitch mounted thereon, a target configured separate from and adjacent to the keyswitch and the substrate, and a sensing element configured on the substrate and operable to generate displacement data corresponding to a displacement between the sensing element and the target. The substrate is operable to bend in response to receiving a threshold force transferred from the keyswitch to the substrate. A force measurement is generated based on the displacement data, the force measurement corresponding to an amount of a change in the displacement between the sensing element and the target as the substrate bends.

### BACKGROUND

Input devices are commonplace in modern life and are typically used to convert human-induced analog inputs (e.g., touches, clicks, motions, touch gestures, button presses, scroll wheel rotations, etc.) made in conjunction with an input device into digital signals for computer processing. An input device can include any device that can provide data and control signals to a computing system. Some non-limiting examples of input devices include computer mice, keyboards, virtual reality and/or augmented reality controllers, touch pads, remote controls, gaming controllers, joysticks, trackballs, and the like. Some non-limiting examples of computing systems include desktop computers, laptop computers, netbook computers, gaming consoles, tablets and “phablet” computers, smart phones, personal digital assistants, wearable devices (e.g., smart watches, glasses), virtual reality (VR) and/or augmented reality (AR) headsets and systems, internet-of-things (IoT) devices, and the like.

Some contemporary input devices, such as keyboards and computer mice, improved ergonomics and greater functionality has been incorporated in a variety of ways, including programmable buttons, higher resolution buttons and rotary devices, faster communication for reduced latency, and more. Despite these many improvements, more innovation in functionality and control are needed to improve the user experience and provide new options for application control and usage.

Unless otherwise indicated herein, the materials described in this section are not prior art to the claims in this application and are not admitted to be prior art by inclusion in this section.

### BRIEF SUMMARY

In some embodiments, a system for a keyed input device includes: a substrate (e.g., printed circuit board); a keyswitch mounted on the substrate; a target configured separate from and adjacent to the keyswitch and the substrate; and a sensing element configured on the substrate, the sensing element operable to generate displacement data corresponding to a displacement between the sensing element and the target, wherein the substrate is operable to bend in response to receiving a threshold force transferred from the keyswitch to the substrate, and wherein a force measurement is generated based on the displacement data, the force measurement corresponding to an amount of a change in the displacement between the sensing element and the target as the substrate bends. The system can further include one or more processors, wherein the sensing element is comprised of an inductive coil operable to generate a first magnetic field in response to an induced current, wherein the target generates a second magnetic field in response to receiving the first magnetic field, the second magnetic field opposing the first magnetic field, wherein the one or more processors generates the force measurement, at least in part, by detecting an inductance of the inductive coil, and wherein the inductance of the inductive coil changes based on an amount of the second magnetic field received by the sensing element. The target is an electrically conductive material. In some aspects, the system includes a metal frame, and wherein the target is the metal frame. In some embodiments, the threshold force transferred from the keyswitch to the substrate is higher than a bottom-out force of the keyswitch, such that a non-zero force measurement only occurs when the keyswitch is fully pressed. In certain embodiments, the substrate is configured to bend less than a threshold amount (e.g., <1 mm). A stopper can be used that prevents the substrate from bending more than the threshold amount.

In certain embodiments, a force sensing system for a keyed input device includes: a flexible substrate configured to bend in response to receiving a threshold force; a target comprised of an electrically conductive material is configured separate from and adjacent to the substrate; a sensing element configured on the substrate, the sensing element operable to generate displacement data corresponding to a displacement between the sensing element on the substrate and the target; and one or more processors configured to: receive the displacement data; and generate a force measurement of a force imparted on the flexible substrate based on the displacement data, the force measurement corresponding to an amount of a change in the displacement between the sensing element and the target as the substrate bends. In some aspects, the target (e.g., an electrically conductive material) is fixed and does not move (e.g., immobile). In some embodiments, the sensing element is comprised of an inductive coil operable to generate a first magnetic field in response to an induced current, wherein the target generates a second magnetic field in response to receiving the first magnetic field, the second magnetic field opposing the first magnetic field, wherein the one or more processors generates the force measurement, at least in part, by detecting an inductance of the inductive coil, and wherein the inductance of the inductive coil changes based on an amount of the second magnetic field received by the sensing element. In some implementations, the system includes a frame, and wherein the target is coupled to the frame. In some cases, the target can be the frame.

In some cases, a method of operating a keyed device can include generating, by a sensing element configured on a substrate of the keyed device, first displacement data that corresponds to a displacement between the sensing element and a target configured separate from and adjacent to the substrate, the substrate including a keyswitch mounted thereon; receiving, by the keyswitch, a pressing force that causes the substrate to bend a threshold amount; generating, by the sensing element, second displacement data that corresponds to a change in the displacement between the sensing element and a target; and determining, by one or more processors, a force measurement corresponding to the pressing force based on the first displacement data and the second displacement data, and an amount of a change in the displacement between the sensing element and the target as the substrate bends. In some aspects, the sensing element is comprised of an inductive coil operable to generate a first magnetic field in response to an induced current, wherein the target generates a second magnetic field in response to receiving the first magnetic field, the second magnetic field opposing the first magnetic field, wherein the one or more processors generates the force measurement, at least in part, by detecting an inductance of the inductive coil, and wherein the inductance of the inductive coil changes based on an amount of the second magnetic field received by the sensing element. In some embodiments, the keyed device includes a frame and the target is coupled to the frame. In certain embodiments, the target is the frame.

In some embodiments, a computer mouse comprises: a housing; a keyplate coupled to the housing, the keyplate configured to be depressed along a range of motion; a first substrate (e.g. a printed circuit board) disposed in the housing; a keyswitch mounted on the first substrate, the keyplate configured activate the keyswitch when the keyplate is depressed a threshold distance; a sensing element coupled to the first substrate; a second substrate coupled to the housing; and a target mounted on the second substrate, the sensing element operable to generate displacement data corresponding to a displacement between the sensing element and the target, wherein the first substrate is operable to bend in response to receiving a threshold force transferred from the keyswitch to the first substrate when the keyplate is depressed, and wherein a force measurement is generated based on the displacement data, the force measurement corresponding to an amount of a change in the displacement between the sensing element and the target as the substrate bends. In some embodiments, the second substrate is part of or is integrated with a portion of the housing. In certain embodiments, the computer mouse further includes one or more processors, wherein the sensing element is comprised of an inductive coil operable to generate a first magnetic field in response to an induced current, wherein the target generates a second magnetic field in response to receiving the first magnetic field, the second magnetic field opposing the first magnetic field, wherein the one or more processors generates the force measurement, at least in part, by detecting an inductance of the inductive coil, and wherein the inductance of the inductive coil changes based on an amount of the second magnetic field received by the sensing element. In some embodiments, the threshold force transferred from the keyswitch to the first substrate is higher than a bottom-out force of the keyswitch, such that a non-zero force measurement only occurs when the keyswitch is fully pressed. In some embodiments, the threshold force transferred from the keyswitch is lower than an actuation force of the keyswitch, wherein the force measurement is used to confirm a keypress event.

The terms and expressions that have been employed are used as terms of description and not of limitation, and there is no intention in the use of such terms and expressions of excluding any equivalents of the features shown and described or portions thereof. It is recognized, however, that various modifications are possible within the scope of the systems and methods claimed. Thus, although the present system and methods have been specifically disclosed by examples and optional features, modification and variation of the concepts herein disclosed should be recognized by those skilled in the art, and such modifications and variations are considered to be within the scope of the systems and methods as defined by the appended claims.

This summary is not intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim.

The foregoing, together with other features and examples, will be described in more detail below in the following description, claims, and accompanying drawings.

### BRIEF DESCRIPTION OF THE DRAWINGS

The features of the various embodiments described above, as well as other features and advantages of certain embodiments of the present invention, will be more apparent from the following detailed description taken in conjunction with the accompanying drawings, in which:

FIG. 1 shows a simplified example of a computer system that can include any of a variety of host computing devices and computer peripheral devices, including computer peripheral devices (e.g., keyboards and computer mice) that can be configured to perform aspects of the various inventive concepts described herein;

FIG. 2 shows a system for operating a computer peripheral device, according to certain embodiments;

FIG. 3 is a simplified block diagram of a host computing device, according to certain embodiments;

FIGS. 4A-4F show a key press sequence for a key structure with position and force sensing capabilities, according to certain embodiments;

FIGS. 5A and 5B show a keypress sequence for a keyed device with force detection, according to certain embodiments;

FIG. 5C-5D show various embodiments of a keyswitch mounted on a flexible PCB, according to certain embodiments;

FIG. 5E-5H show various embodiments of a keyswitch mounted on a flexible PCB, according to certain embodiments;

FIG. 6 shows a substrate with an array mounting sites for keyswitches, according to certain embodiments;

FIGS. 7A and 7B show a keypress sequence for a computer mouse with force detection, according to certain embodiments;

FIGS. 8A and 8B show a keypress sequence for a computer mouse 800 with force detection, according to some embodiments;

FIGS. 9A and 9B show a keypress sequence for a computer mouse 900 with force detection, according to some embodiments;

FIG. 10 is a simplified flow chart showing aspects of a method for force sensing on an keyed input device, according to certain embodiments.

Throughout the drawings, it should be noted that like reference numbers are typically used to depict the same or similar elements, features, and structures.

### DETAILED DESCRIPTION

Aspects of the present disclosure relate generally to computer peripheral devices, and more particularly to keyed input devices (e.g., keyboards and computer mice) with force sensing architectures, according to certain embodiments.

In the following description, various examples of computer peripheral devices with force sensing architectures are described. For the purpose of explanation, specific configurations and details are set forth to provide a thorough understanding of the embodiments. However, it will be apparent to one skilled in the art that certain embodiments may be practiced or implemented without every detail disclosed. Furthermore, well-known features may be omitted or simplified to prevent any obfuscation of the novel features described herein.

The following high-level summary is intended to provide a basic understanding of some of the novel innovations depicted in the figures and presented in the corresponding descriptions provided below. Aspects of the invention relate to novel force-sensing integration concepts in keyed devices that can be implemented with a keyswitch infrastructure not initially configured for force sensing. This can be done, for instance, by sensing an amount that a substrate (e.g., printed circuit board or “PCB”) supporting the keyswitch flexes in response to a force applied during a key press or button press event. For instance, a user may press a keycap on a keyswitch, causing the keyswitch to trigger a keypress event once a threshold keypress force is met. Additional force may cause the underlying substrate to flex (e.g., bend downwards), which can be measured. Measurement may be done by optical sensing, magnetic sensing (as further described below), time-of-flight type measurements, or other suitable method of measuring an amount of flexion. The amount that the substrate flexes can be correlated to an amount of force applied, which in turn may be used to provide force sensing in a key press. Thus, force sensing can be made possible with keyswitches (e.g., galvanic, analog, or both) not normally including force sensing functionality.

By way of a non-limiting example, some implementations of such systems for keyed input devices (e.g., keyboards, computer mice, etc.) may include a substrate (e.g., PCB), a keyswitch (e.g., galvanic, analog, or both) mounted on the substrate, a target (e.g., an electrically conductive element, including metals, ferromagnetic materials, and paramagnetic materials, and the like) configured separate from and adjacent to the keyswitch and the substrate, and a sensing element (e.g., Hall Sensor, TMR sensor, inductive sensing, optical sensing, capacitive sensing) configured on the substrate, the sensing element operable to generate displacement data corresponding to a displacement between the sensing element and the target, wherein the substrate is operable to bend in response to receiving a threshold force transferred from the keyswitch to the substrate, and wherein a force measurement is generated based on the displacement data, the force measurement corresponding to an amount of a change in the displacement between the sensing element and the target as the substrate bends. In some aspects, the sensing element is comprised of an inductive coil operable to generate a first magnetic field in response to an induced current, the target generates a second magnetic field in response to receiving the first magnetic field, the second magnetic field opposing the first magnetic field, and one or more processors generates the force measurement, at least in part, by detecting an inductance of the inductive coil, where the inductance of the inductive coil changes based on an amount of the second magnetic field received by the sensing element. Thus, some novel features in certain embodiments presented herein include, but are not limited to, a sensing element (e.g., the coil on the PCB/substrate) that moves/bend and a fixed target; a multi-purpose target where the target is both used for the sensing and for the frame of the device; and having secondary functions where the force sensor is used in addition to a standard keyswitch, and is enabled when the force applied on the keyswitch is higher than a given threshold force. However, other novel implementations are possible and are presented below.

It is to be understood that this high-level summary is presented to provide the reader with a baseline understanding of some of the novel aspects of the present disclosure and a roadmap to the details that follow. This high-level summary in no way limits the scope of the various embodiments described throughout the detailed description and each of the figures referenced above are further described below in greater detail and in their proper scope.

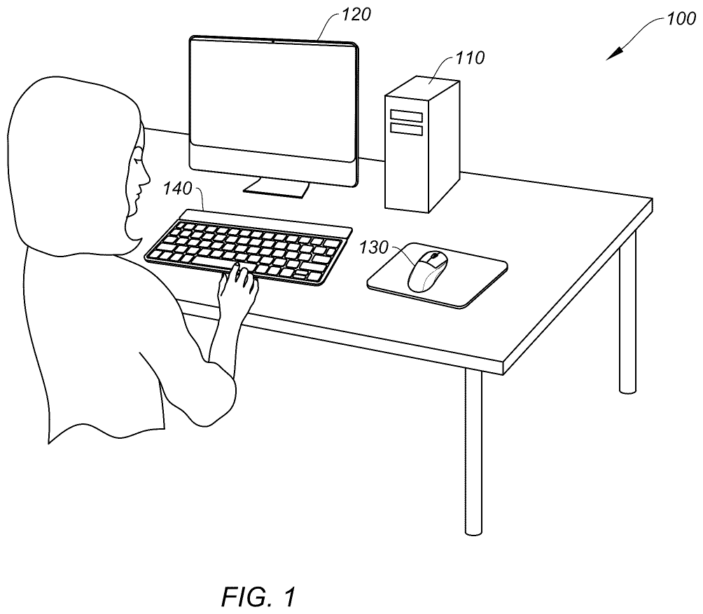

FIG. 1 shows a simplified example of a computer system 100 that can include any of a variety of host computing devices and computer peripheral devices, including computer peripheral devices (e.g., a computer mouse, keyboard, etc.) that can be configured to perform aspects of the various inventive concepts described herein. Computer system 100 can include computer 110, monitor 120, computer mouse 130, and keyboard 140. In some cases, keyboard 140 can be a “qwerty” style keyboard, or any suitable input device (e.g., internet-of-things device, AR/VR controller, remote controller, or the like) with one or more keys that can be configured as analog keys with travel and force detection, as further described throughout this disclosure. For computer system 100, keyboard 140 can be configured to control various aspects of computer 110 and monitor 120, as would be appreciated by one of ordinary skill in the art with the benefit of this disclosure. The monitor 120, computer mouse 130, and keyboard 140 may be referred to generally as “computer peripheral devices” or “input devices.” Computer peripheral devices 120-140 can be communicatively coupled to host computing device 110 and, in some cases, may be coupled to multiple host computing devices. Although many of the examples presented herein utilize keyswitches in a keyboard-type computer peripheral device, it would be understood by those of ordinary skill in the art with the benefit of this disclosure that the usage of such structures can be applied to other types of input devices.

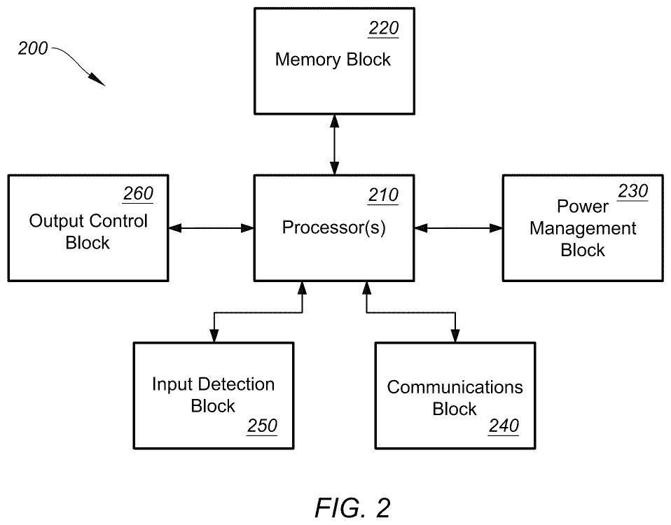

Computer 110 can be any suitable computing device including, but not limited to, a desktop computer, a laptop computer, a tablet or “phablet” computer, a smartphone, a PDA, a wearable device (e.g., smart watches, smart glasses), virtual reality/augmented reality (VR/AR) system, or the like. A host computing device may also be referred to herein as a “host computer,” “host device,” “computing device,” “computer,” or the like, and may include a machine-readable medium (not shown) configured to store computer code, such as driver software, firmware, and the like, where the computer code may be executable by one or more processors of the host computing device(s) (see, e.g., processor(s) 210 of FIG. 2) to control aspects of the host computing device, for instance, via the one or more computer peripheral devices.

FIG. 2 shows a system 200 for operating a computer peripheral device (e.g., computer mouse 130, keyboard 140, etc.), according to certain embodiments. System 200 may be configured to operate any of the computer peripheral devices shown or not shown herein but within the wide purview of the present disclosure. System 200 may include processor(s) 210, a memory 220, a power management system 230, a communication module 240, an input detection module 250, and an output control module 260. Each of the system blocks 220-260 can be in electronic communication with processor(s) 210 (e.g., via a bus system). System 200 may include additional functional blocks that are not shown or discussed to prevent obfuscation of the novel features described herein. System blocks 220-260 (also referred to as “modules”) may be implemented as separate blocks, or alternatively, more than one system block may be implemented in a single block. In the context described herein, system 200 can be incorporated into any computer peripheral devices (e.g., input devices) described or mentioned herein and may be further configured with any of the systems presented herein, as would be appreciated by one of ordinary skill in the art with the benefit of this disclosure.

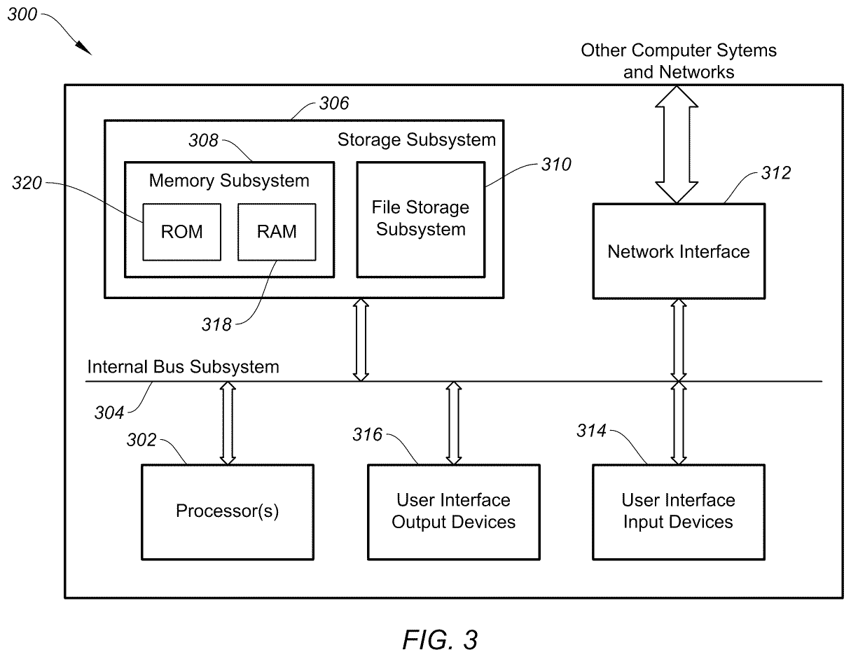

In certain embodiments, processor(s) 210 may include one or more microprocessors and can be configured to control the operation of system 200. Alternatively or additionally, processor(s) 210 may include one or more microcontrollers (MCUs), digital signal processors (DSPs), or the like, with supporting hardware and/or firmware (e.g., memory, programmable I/Os, etc.), and/or software, as would be appreciated by one of ordinary skill in the art. Processor(s) 210 can control some or all aspects of the operation of keyboard 140 (e.g., system blocks 220-260). Alternatively or additionally, some of system blocks 220-260 may include an additional dedicated processor, which may work in conjunction with processor(s) 210. For instance, MCUs, μCs, DSPs, and the like, may be configured in other system blocks of system 200. Communications block 240 may include a local processor, for instance, to control aspects of communication with host computer 110 (e.g., via Bluetooth, Bluetooth LE, RF, IR, hardwire, ZigBee, Z-Wave, Logitech Unifying, or other communication protocol). Processor(s) 210 may be local to the computer peripheral device (e.g., contained therein), may be external to the computer peripheral device (e.g., off-board processing, such as by a corresponding host computing device), or a combination thereof. Processor(s) 210 may perform any of the various functions and methods described and/or covered by this disclosure in conjunction with any other system blocks in system 200. In some implementations, processor 302 of FIG. 3 may work in conjunction with processor(s) 210 to perform some or all of the various methods described throughout this disclosure. In some embodiments, multiple processors may enable increased performance characteristics in system 200 (e.g., speed and bandwidth), however, multiple processors are not required, nor necessarily germane to the novelty of the embodiments described herein. One of ordinary skill in the art would understand the many variations, modifications, and alternative embodiments that are possible.

Memory block (“memory”) 220 can store one or more software programs to be executed by one or more processors (e.g., processor(s) 210). It should be understood that “software” can refer to sequences of instructions that, when executed by processing unit(s) (e.g., processors, processing devices, etc.), cause system 200 to perform certain operations of software programs. The instructions can be stored as firmware residing in read-only memory (ROM), and/or applications stored in media storage that can be read into memory for execution by processing devices (e.g., processor(s) 210). Software can be implemented as a single program or a collection of separate programs and can be stored in non-volatile storage and copied in whole or in part to volatile working memory during program execution. In some embodiments, memory 220 may store data corresponding to inputs on the computer peripheral device, such as a detected movement of the computer peripheral device, a sensor (e.g., optical sensor, accelerometer, etc.), activation of one or more input elements (e.g., buttons, sliders, touch-sensitive regions, etc.), or the like. Stored data may be aggregated and sent via reports to a host computing device.

In certain embodiments, memory 220 can store the various data described throughout this disclosure. Memory 220 can be used to store any suitable data to perform any function described herein and as would be appreciated by one of ordinary skill in the art with the benefit of this disclosure. Memory 220 can be referred to as a storage system or storage subsystem and can store one or more software programs to be executed by processors (e.g., in processor(s) 210). It should be understood that “software” can refer to sequences of instructions that, when executed by processing unit(s) (e.g., processors, processing devices, etc.), cause system 200 to perform certain operations of software programs. The instructions can be stored as firmware residing in read-only memory (ROM) and/or applications stored in media storage that can be read into memory for processing by processing devices. Software can be implemented as a single program or a collection of separate programs and can be stored in non-volatile storage and copied in whole or in part to volatile working memory during program execution. From a storage subsystem, processing devices can retrieve program instructions to execute various operations (e.g., software-controlled switches, etc.) as described herein.

Power management system 230 can be configured to manage power distribution, recharging, power efficiency, and the like. In some embodiments, power management system 230 can include a battery (not shown), a Universal Serial Bus (USB)-based recharging system for the battery (not shown), and power management devices (e.g., voltage regulators-not shown), and a power grid within system 200 to provide power to each subsystem (e.g., communications block 240, etc.). In certain embodiments, the functions provided by power management system 230 may be incorporated into processor(s) 210. Alternatively, some embodiments may not include a dedicated power management block. For example, functional aspects of power management block 240 may be subsumed by another block (e.g., processor(s) 210) or in combination therewith. The power source can be a replaceable battery, a rechargeable energy storage device (e.g., super capacitor, Lithium Polymer Battery, NiMH, NiCd), or a corded power supply. The recharging system can be an additional cable (specific for the recharging purpose), or it can use a USB connection to recharge the battery.

Communication system 240 can be configured to enable wireless communication with a corresponding host computing device (e.g., 110), or other devices and/or computer peripherals, according to certain embodiments. Communication system 240 can be configured to provide radiofrequency (RF), Near-Field Communication (NFC), Bluetooth®, Logitech proprietary communication protocol (e.g., Unifying, Gaming Lightspeed, or others), infra-red (IR), ZigBee®, Z-Wave, or other suitable communication technology to communicate with other computing devices and/or peripheral devices. System 200 may optionally comprise a hardwired connection to the corresponding host computing device. For example, computer peripheral device 140 can be configured to receive a USB, FireWire®, Thunderbolt®, or other universal-type cables to enable bi-directional electronic communication with the corresponding host computing device or other external devices. Some embodiments may utilize different types of cables or connection protocol standards to establish hardwired communication with other entities. In some aspects, communication ports (e.g., USB), power ports, etc., may be considered as part of other blocks described herein (e.g., input detection module 250, output control module 260, etc.). In some aspects, communication system 240 can send reports generated by the processor(s) 210 (e.g., HID data, streaming or aggregated data, etc.) to a host computing device. In some cases, the reports can be generated by the processor(s) only, in conjunction with the processor(s), or other entity in system 200. Communication system 240 may incorporate one or more antennas, oscillators, etc., and may operate at any suitable frequency band (e.g., 2.4 GHz), etc. One of ordinary skill in the art with the benefit of this disclosure would appreciate the many modifications, variations, and alternative embodiments thereof.

Input detection module 250 can control the detection of a user-interaction with input elements on an input device. For instance, input detection module 250 can detect user inputs from motion sensors, keys, or buttons (e.g., depressible elements), roller wheels, scroll wheels, track balls, touch pads (e.g., one and/or two-dimensional touch sensitive touch pads), click wheels, dials, keypads, microphones, GUIs, touch-sensitive GUIs, proximity sensors (e.g., IR, thermal, Hall effect, inductive sensing, etc.), an image sensor based detection such as gesture detection (e.g., via webcam), audio based detection such as voice input (e.g., via microphone), or the like, as would be appreciated by one of ordinary skill in the art with the benefit of this disclosure. Alternatively, the functions of input detection module 250 or subset thereof can be subsumed by processor(s) 210, or in combination therewith.

In some embodiments, input detection module 250 can detect a touch or touch gesture on one or more touch sensitive surfaces on keyboard 140. Input detection block 250 can include one or more touch sensitive surfaces or touch sensors. Touch sensors generally comprise sensing elements suitable to detect a signal such as direct contact, electromagnetic or electrostatic fields, or a beam of electromagnetic radiation. Touch sensors can typically detect changes in a received signal, the presence of a signal, or the absence of a signal. A touch sensor may include a source for emitting the detected signal, or the signal may be generated by a secondary source. Touch sensors may be configured to detect the presence of an object at a distance from a reference zone or point (e.g., <5 mm), contact with a reference zone or point, or a combination thereof. Certain embodiments of computer peripheral device 140 may or may not utilize touch detection or touch sensing capabilities.

Input detection block 250 can include touch and/or proximity sensing capabilities. Some examples of the types of touch/proximity sensors may include, but are not limited to, resistive sensors (e.g., air-gap 4-wire based, based on carbon loaded plastics which have different electrical characteristics depending on the pressure (FSR), interpolated FSR, strain gages, etc.), capacitive sensors (e.g., surface capacitance, self-capacitance, mutual capacitance, etc.), optical sensors (e.g., light barrier type (default open or closed), infrared light barriers matrix, laser based diode coupled with photo-detectors that could measure the time of flight of the light path, etc.), acoustic sensors (e.g., piezo-buzzer coupled with microphones to detect the modification of a wave propagation pattern related to touch points, etc.), inductive sensors, magnetic sensors (e.g., Hall Effect, etc.), or the like.

Input detection module 250 may include a movement tracking sub-block that can be configured to detect a relative displacement (movement tracking) of a computer peripheral device. For example, input detection module 250 optical sensor(s) such as IR LEDs and an imaging array of photodiodes to detect the movement of a computer peripheral device relative to an underlying surface. A computer peripheral device may optionally include movement tracking hardware that utilizes coherent (laser) light. Movement tracking can provide positional data (e.g., delta X and delta Y data from the last sampling) or lift detection data. For example, an optical sensor can detect when a user lifts the computer peripheral device (e.g., computer mouse 130) off an underlying surface (also referred to as a “work surface”) and can send that data to processor(s) 210 for further processing. In some embodiments, processor(s) 210, the movement tracking block (which may include an additional dedicated processor), or a combination thereof, as would be appreciated by one of ordinary skill in the art with the benefit of this disclosure.

In certain embodiments, accelerometers can be used for movement detection. Accelerometers can be electromechanical devices (e.g., micro-electromechanical systems (MEMS) devices) configured to measure acceleration forces (e.g., static and dynamic forces). One or more accelerometers can be used to detect three-dimensional (3D) positioning. For example, 3D tracking can utilize a three-axis accelerometer or two two-axis accelerometers (e.g., in a “3D air mouse,” HMD, or another device). Accelerometers can further determine if the computer peripheral device has been lifted off an underlying surface and can provide movement data that may include the velocity, physical orientation, and acceleration of a computer peripheral device. In some embodiments, gyroscope(s) can be used in lieu of or in conjunction with accelerometer(s) to determine movement or input device orientation.

In some embodiments, input detection block 250 can control aspects of one or more sensing elements, as described herein. For example, input detection block 250 can control a sensing element including a first sensing section configured to detect the movement of a depressible plunger (e.g., with a key cap) along the first range of motion and generate corresponding first data and a second sensing section configured to detect movement of the depressible plunger along the second range of motion and generate corresponding second data. In such cases, processor(s) 210 may be configured to determine a position of the plunger (e.g., target coupled to the plunger) along the first range of motion based on the first data and determine a force produced by the plunger on the dampening element, while the plunger moves along the second range of motion, based on the second data, as further described below.

In some embodiments, output control module 260 can control various outputs for a corresponding computer peripheral device. For instance, output control module 260 may control a number of visual output elements (e.g., LEDs, LCD or LED screens/keys), displays, audio outputs (e.g., speakers), haptic output systems, or the like. One of ordinary skill in the art with the benefit of this disclosure would appreciate the many modifications, variations, and alternative embodiments thereof.

Although certain systems may not be expressly discussed, they should be considered as part of system 200, as would be understood by one of ordinary skill in the art. For example, system 200 may include a bus subsystem to transfer power and/or data to and from the different systems therein. It should be appreciated that system 200 is illustrative and that variations and modifications are possible. System 200 can have other capabilities not specifically described herein. Further, while system 200 is described with reference to particular blocks, it is to be understood that these blocks are defined for convenience of description and are not intended to imply a particular physical arrangement of component parts. Further, the blocks need not correspond to physically distinct components. Blocks can be configured to perform various operations (e.g., by programming a processor or providing appropriate control circuitry) and various blocks might or might not be reconfigurable depending on how the initial configuration is obtained.

Embodiments of the present invention can be realized in a variety of apparatuses including electronic devices (e.g., computer peripheral devices) implemented using any combination of circuitry and software. Furthermore, aspects and/or portions of system 200 may be combined with or operated by other subsystems as required by design. For example, input detection module 250 and/or memory 220 may operate within processor(s) 210 instead of functioning as separate entities. In addition, the inventive concepts described herein can also be applied to any electronic device. Further, system 200 can be applied to any of the computer peripheral devices described in the embodiments herein, whether explicitly, referentially, or tacitly described (e.g., would have been known to apply to a particular computer peripheral device by one of ordinary skill in the art). The foregoing embodiments are not intended to be limiting and those of ordinary skill in the art with the benefit of this disclosure would appreciate the myriad applications and possibilities.

FIG. 3 is a simplified block diagram of a host computing device 300, according to certain embodiments. Host computing device 300 can implement some or all functions, behaviors, and/or capabilities described herein that would use electronic storage or processing, as well as other functions, behaviors, or capabilities not expressly described. Host computing device 300 can include a processing subsystem (processor(s)) 302, a storage subsystem 306, user interfaces 314, 316, and a communication interface 312. Computing device 300 can also include other components (not explicitly shown) such as a battery, power controllers, and other components operable to provide various enhanced capabilities. In various embodiments, host computing device 300 can be implemented in any suitable computing device, such as a desktop or laptop computer (e.g., desktop 110), mobile device (e.g., tablet computer, smart phone, mobile phone), wearable device, media device, or the like, or in peripheral devices (e.g., keyboards, etc.) in certain implementations.

Processor(s) 302 can include MCU(s), micro-processors, application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, or electronic units designed to perform a function, portions of functions, or a combination of methods, functions, etc., described throughout this disclosure.

Storage subsystem 306 can be implemented using a local storage and/or removable storage medium, e.g., using disk, flash memory (e.g., secure digital card, universal serial bus flash drive), or any other non-transitory storage medium, or a combination of media, and can include volatile and/or non-volatile storage media. Local storage can include a memory subsystem 308 including random access memory (RAM) 318 such as dynamic RAM (DRAM), static RAM (SRAM), synchronous dynamic RAM (e.g., DDR), or battery backed-up RAM or read-only memory (ROM) 320, or a file storage subsystem 310 that may include one or more code modules. In some embodiments, storage subsystem 306 can store one or more applications and/or operating system programs to be executed by processing subsystem 302, including programs to implement some or all operations described above that would be performed using a computer. For example, storage subsystem 306 can store one or more code modules for implementing one or more method steps described herein.

A firmware and/or software implementation may be implemented with modules (e.g., procedures, functions, and so on). A machine-readable medium tangibly embodying instructions may be used in implementing the methodologies described herein. Code modules (e.g., instructions stored in memory) may be implemented within a processor or external to the processor. As used herein, the term “memory” refers to a type of long term, short term, volatile, nonvolatile, or other storage medium, and is not to be limited to any particular type of memory or number of memories, or type of media upon which memory is stored.

Moreover, the term “storage medium” or “storage device” may represent one or more memories for storing data, including read only memory (ROM), RAM, magnetic RAM, core memory, magnetic disk storage mediums, optical storage mediums, flash memory devices and/or other machine-readable mediums for storing information. The term “machine-readable medium” includes, but is not limited to, portable or fixed storage devices, optical storage devices, wireless channels, and/or various other storage mediums capable of storing instruction(s) and/or data.

Furthermore, embodiments may be implemented by hardware, software, scripting languages, firmware, middleware, microcode, hardware description languages, and/or any combination thereof. When implemented in software, firmware, middleware, scripting language, and/or microcode, program code or code segments to perform tasks may be stored in a machine-readable medium such as a storage medium. A code segment (e.g., code module) or machine-executable instruction may represent a procedure, a function, a subprogram, a program, a routine, a subroutine, a module, a software package, a script, a class, or a combination of instructions, data structures, and/or program statements. A code segment may be coupled to another code segment or a hardware circuit by passing and/or receiving information, data, arguments, parameters, and/or memory contents. Information, arguments, parameters, data, etc. may be passed, forwarded, or transmitted by suitable means including memory sharing, message passing, token passing, network transmission, etc. These descriptions of software, firmware, storage mediums, etc., apply to systems 200 and 300, as well as any other implementations within the wide purview of the present disclosure. In some embodiments, aspects of the invention (e.g., surface classification) may be performed by software stored in storage subsystem 306, stored in memory 220 of a computer peripheral device, or both. One of ordinary skill in the art with the benefit of this disclosure would appreciate the many modifications, variations, and alternative embodiments thereof.

Implementation of the techniques, blocks, steps, and means described throughout the present disclosure may be done in various ways. For example, these techniques, blocks, steps, and means may be implemented in hardware, software, or a combination thereof. For a hardware implementation, the processing units may be implemented within one or more ASICs, DSPs, DSPDs, PLDs, FPGAs, processors, controllers, micro-controllers, microprocessors, other electronic units designed to perform the functions described above, and/or a combination thereof.

Each code module may comprise sets of instructions (codes) embodied on a computer-readable medium that directs a processor of a host computing device 110 to perform corresponding actions. The instructions may be configured to run in sequential order, in parallel (such as under different processing threads), or in a combination thereof. After loading a code module on a general-purpose computer system, the general-purpose computer is transformed into a special-purpose computer system.

Computer programs incorporating various features described herein (e.g., in one or more code modules) may be encoded and stored on various computer readable storage media. Computer readable media encoded with the program code may be packaged with a compatible electronic device, or the program code may be provided separately from electronic devices (e.g., via Internet download or as a separately packaged computer readable storage medium). Storage subsystem 306 can also store information useful for establishing network connections using the communication interface 312.

Computer system 300 may include user interface input devices 314 elements (e.g., touch pad, touch screen, scroll wheel, click wheel, dial, button, switch, keypad, microphone, etc.), as well as user interface output devices 316 (e.g., video screen, indicator lights, speakers, headphone jacks, virtual- or augmented-reality display, etc.), together with supporting electronics (e.g., digital to analog or analog to digital converters, signal processors, etc.). A user can operate input devices of user interface 314 to invoke the functionality of computing device 300 and can view and/or hear output from computing device 300 via output devices of user interface 316.

Processing subsystem 302 can be implemented as one or more processors (e.g., integrated circuits, one or more single core or multi core microprocessors, microcontrollers, central processing unit, graphics processing unit, etc.). In operation, processing subsystem 302 can control the operation of computing device 300. In some embodiments, processing subsystem 302 can execute a variety of programs in response to program code and can maintain multiple concurrently executing programs or processes. At a given time, some or all of a program code to be executed can reside in processing subsystem 302 and/or in storage media, such as storage subsystem 304. Through programming, processing subsystem 302 can provide various functionality for computing device 300. Processing subsystem 302 can also execute other programs to control other functions of computing device 300, including programs that may be stored in storage subsystem 304.

Communication interface (also referred to as network interface) 312 can provide voice and/or data communication capability for computing device 300. In some embodiments, communication interface 312 can include radio frequency (RF) transceiver components for accessing wireless data networks (e.g., Wi-Fi network; 3G, 4G/LTE, 5G; etc.), mobile communication technologies, components for short range wireless communication (e.g., using Bluetooth communication standards, NFC, etc.), other components, or combinations of technologies. In some embodiments, communication interface 312 can provide wired connectivity (e.g., universal serial bus (USB), Ethernet, universal asynchronous receiver/transmitter, etc.) in addition to, or in lieu of, a wireless interface. Communication interface 312 can be implemented using a combination of hardware (e.g., driver circuits, antennas, modulators/demodulators, encoders/decoders, and other analog and/or digital signal processing circuits) and software components. In some embodiments, communication interface 312 can support multiple communication channels concurrently.

User interface input devices 314 may include any suitable computer peripheral device (e.g., computer mouse, keyboard, gaming controller, remote control, stylus device, etc.), as would be appreciated by one of ordinary skill in the art with the benefit of this disclosure. User interface output devices 316 can include display devices (e.g., a monitor, television, projection device, etc.), audio devices (e.g., speakers, microphones), haptic devices, etc. Note that user interface input and output devices are shown to be a part of system 300 as an integrated system. In some cases, such as in laptop computers, this may be the case as keyboards and input elements as well as display and output elements are integrated on the same host computing device. In some cases, the input and output devices may be separate from system 300, as shown in FIG. 1. One of ordinary skill in the art with the benefit of this disclosure would appreciate the many modifications, variations, and alternative embodiments thereof.

It will be appreciated that computing device 300 is illustrative and that variations and modifications are possible. A host computing device can have various functionality not specifically described (e.g., voice communication via cellular telephone networks) and can include components appropriate to such functionality. While the computing device 300 is described with reference to particular blocks, it is to be understood that these blocks are defined for convenience of description and are not intended to imply a particular physical arrangement of component parts. For example, processing subsystem 302, storage subsystem 306, user interfaces 314, 316, and communications interface 312 can be in one device or distributed among multiple devices. Further, the blocks need not correspond to physically distinct components. Blocks can be configured to perform various operations (e.g., by programming a processor or providing appropriate control circuitry) and various blocks might or might not be reconfigurable depending on how an initial configuration is obtained. Embodiments of the present invention can be realized in a variety of apparatus including electronic devices implemented using a combination of circuitry and software. Host computing devices or even peripheral devices described herein can be implemented using system 300.

### Force Sensing Integration in Mechanical Keyboards

As described above, aspects of the invention incorporate force-sensing integration in mechanical keyboards. A force applied on a key plunger can be measured by detecting how much a substrate flexes, the substrate supporting a keyswitch and plunger. Typically, the substrate will flex at or near the end of the travel range of the key plunger, which operates to extend the sensing range to a “force region,” as further described below. The extended range can further be better for multi-threshold inputs (e.g., first threshold in travel region, second threshold in force region), and depending on the action linked with the thresholds it can be a very intuitive way to interact with the computer/application/game. For example, a first threshold associated with a first range of motion (travel region) can control a first action, while a second threshold associated with a second range of motion (e.g., the force region at or near the bottom of the plunger range of motion), can control a second action. In some cases, the thresholds can be fixed or can incorporate hysteresis to allow different thresholds in downward motions (e.g., pressing) versus upward motions (releasing). Note that while there is benefit during the down motion as highlighted above, there are also benefits on the up motion, as this approach allows detection of an intention of the user to release the key while it is still fully depressed because the force applied on it is being released.

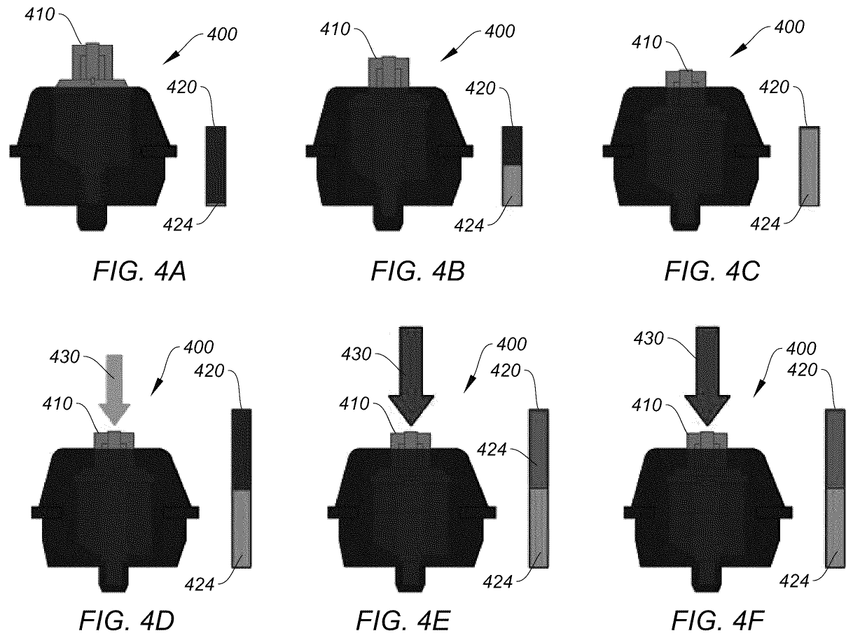

FIGS. 4A-4F show a key press sequence for a key structure 400 with position and force sensing capabilities, according to certain embodiments. Travel/force meter 420 shows how much plunger 410 travels over a combination of a first range of motion 422 and a second range of motion 424 when plunger 410 is depressed. The second range of motion 424 may begin after and be colinear with the first range of motion. Typically, the second range of motion 424 includes motion when force on the plunger 410 causes an underlying substrate (e.g., PCB) to flex, which is measured and associated with a force measurement. In other words, the first range of motion spans from 0 mm travel (non-depressed key/plunger) to approximately 3-4 mm (other ranges are possible) when the plunger comes into contact with a depressible element. The plunger can continue to be depressed over a second range of motion (e.g., <0.5 mm), however with resistance from the flexible substrate that the user can intuitively use to fine tune an amount of force being applied to the key and plunger. In FIG. 4A, plunger 410 of key structure 400 is unpressed and travel/force meter 420 shows that no plunger travel has occurred. In FIG. 4B, plunger 410 is pressed by about 50% over the first range of motion 422, as reflected by travel/force meter 420. In FIG. 4C, plunger 410 is pressed by nearly 95% or more over the first range of motion, as shown in travel/force meter 420. In FIG. 4D, plunger 410 reaches the end of the first range of motion due to the increasing force and causes the underlying substrate to begin flexing (not shown), and movement enters the second range of motion. In some cases a keyswitch may have an actuation force (a force required for a MAKE command to be sent to the computer and when the “haptic” point is felt by the user) of approximately 50 to 60 gf. In some aspects, near the end of the travel a switch is generally between 60 and 90 gf. The force region when the substrate is flexing is typically (though not necessarily) between the 60-90 gf and roughly 250 gf. In FIG. 4E, plunger 410 is pressed by about 50% over the second range of motion, wherein the additional displacement is less than 1 mm and the force 430 has increased substantially. In FIG. 4F, plunger 410 is depressed by about 100% over the second range of motion, reaching greater deflection of the substrate with a corresponding substantially increased force 430.

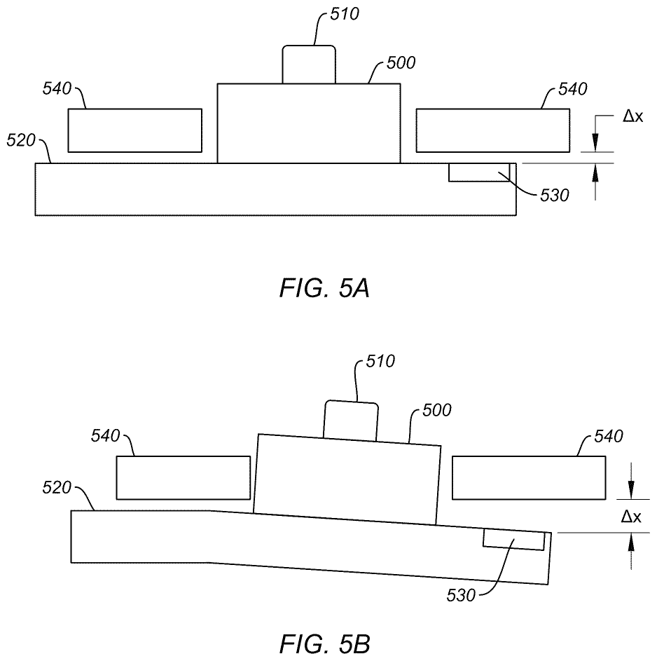

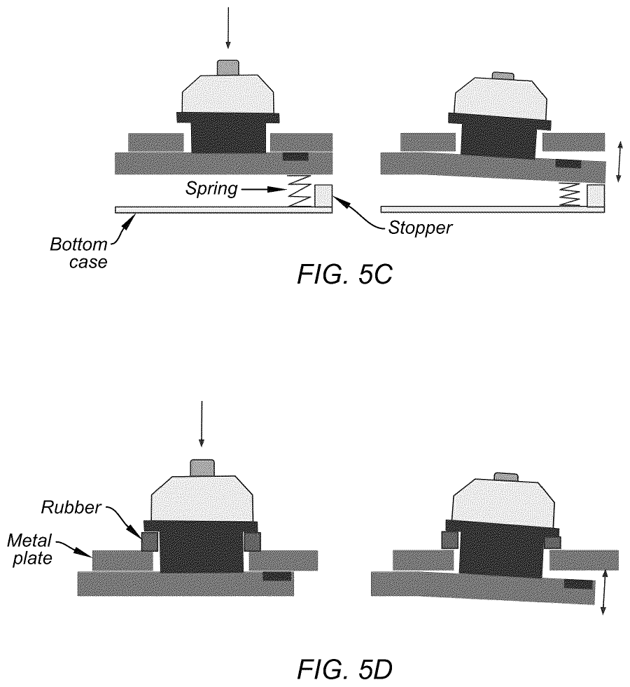

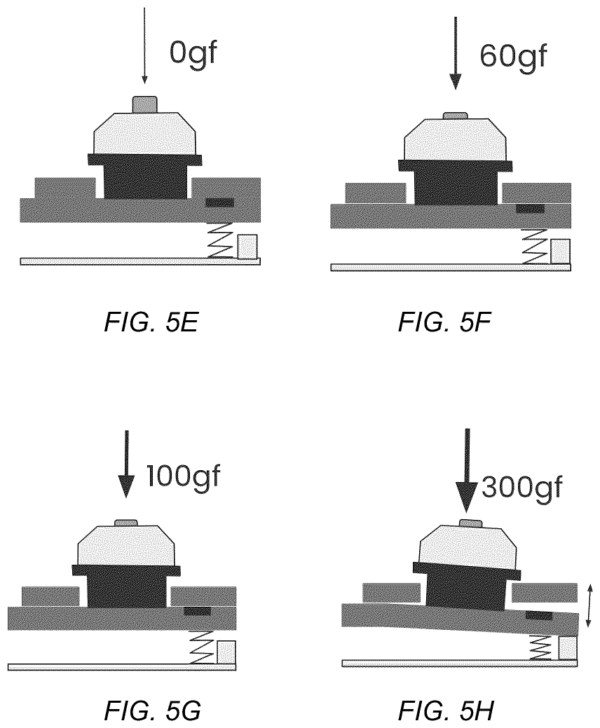

FIGS. 5A and 5B show a keypress sequence for a keyed device with force detection, according to certain embodiments. A keyswitch 500 is mounted on a flexible substrate 520 (e.g., PCB, FPC, molded interconnect device (MID). A frame 540, which may be a keyframe, may be used to house a portion of the keyswitch 500. Keyswitch 500 may or may not be physically coupled to frame 540, which can be used to stabilize the keyswitch within the keyed device (e.g., keyboard). Keyswitch 500 can include a stopper 510 (e.g., typically made of foam or rubber) that can help enable a small displacement of the substrate. For example, when a plunger (not shown) or keyplate (not shown) contacts stopper 510, the stopper may compress slightly (e.g., <0.5 mm) and impart a downward force on the underlying substrate 520. In some embodiments, a stopper can be used to prevent over-loading of the PCB. The PCB is typically designed to be flexible with the stopper providing the force and travel ratio. Depending on the design, the membrane itself could have mechanical properties such that a stopper is not needed. One of ordinary skill in the art with the benefit of this disclosure would appreciate the many modifications, variations, and alternative embodiments thereof.

Frame 540 can include a target comprised of ferromagnetic material and/or paramagnetic material, according to certain embodiments. In some embodiments, frame 540 may be entirely comprised of the ferromagnetic or paramagnetic material (e.g., aluminum), or a target may be coupled to or integrated with frame 540.

A sensor 530 (“sensing element”) can be configured on the substrate 520 and may be operable to generate displacement data corresponding to a displacement between the sensing element and a target on or of frame 540. As the distance (Δx) between the sensing element and target changes (e.g., moves closer together or farther apart), an amount of force applied to the corresponding keyswitch or button can be determined, as further described below. Sensor 530 can be a single sensor or multiple sensors, typically controlled by one or more processors (e.g., processor(s) 210, processors 302, or a combination thereof), which may be onboard or offboard of the keyed device (e.g., keyboard 140). The sensor 530 can be an inductive sensor (e.g., inductive coil configured to detect a magnetic field), capacitive sensor (e.g., operable to detect a change in capacitance to determine a displacement), optical sensor (e.g., analyze pixel data to determine a displacement), time-of-flight (TOF) sensor, ultrasonic sensor, or other type of sensor that can be used to measure the change in displacement between the sensor substrate, as would be appreciated by one or ordinary skill in the art with the benefit of this disclosure, although the embodiments described herein are mostly directed to magnetic field sensing with an inductive coil. Such embodiments, regardless of sensor type, are a technical solution for providing force sensing regardless of keyswitch type including keyed devices that do not use keyswitches, and the force sensing hardware utilizes very little space at or adjacent to a corresponding keyswitch mounting location. Further, there is no need for any particular compatibility with the keyswitch (e.g., a third party keyswitch), as the force sensing function can be wholly or partly independent of the keyswitch function. Certain embodiments described herein allows the integration of force sensing functionality via movement detection.

In some embodiments that employ magnetic sensing, the sensor can include one or more sensing elements comprised of an inductive coil, controlled by one or more processors, that is operable to generate a first magnetic field in response to an induced current. The target, in response to being subject to the first magnetic field, generates a second magnetic field (e.g., due to eddy currents induced by the first magnetic field) that opposes the first magnetic field in polarity that may be directed back to the inductive coil. This second magnetic field interacts with the first, which can vary a measured inductance of the inductive coil. The one or more processors can generate a force measurement, at least in part, by detecting an inductance of the inductive coil, where the inductance of the inductive coil can change based on an amount of the second magnetic field received by the sensing element. That is, the measured inductance of the coil can vary based on how close the sensing element (the inductive coil) is to the target (frame 540). When, for instance, the substrate flexes (see, e.g., the transition between FIG. 5A and FIG. 5B) and the sensor gets farther from the target, fewer eddy currents are induced in the target, a weaker second magnetic field is generated, and thusly the measured inductance of the inductive coil is increased, which can be calibrated to accurately determine a corresponding force measurement. In some embodiments, certain reference points/positions may be used for the calibration. For example, the following reference points/positions (and any combination thereof) can be dynamically measured during the life of the product: (1) the resting position (the smallest sensing value)—the position where the sensing element will be most of the time (i.e., when the applied force is below or equal to the “threshold force” defined in the claims); (2) the maximum (or bottom) position (the biggest sensing value)-the position when the sensor/substrate reaches the stopper is associated with a maximum force that depends on the rigidity of the substrate and the spring (if included), which can be measured during production (e.g., the maximum force can be designed to be between 300 gF and 500 gF; and (4) the click position: if the sensor is enabled during the use of the keyswitch (i.e., the sensor threshold force is lower that the actuation force of the switch), the actuation point of the keyswitch can be used (i.e., the position at which the switch will click, usually around 60 gF) as a reference for the calibration. In some cases, the non-linearity of the sensor can be measured at production and used to linearize each unit by measuring many points (e.g., raw data) within the range of the sensor. These points draw a curve, and an inverse function of this curve can be applied on the sensing data to obtain a more linear line. In cases where the inverse function is too complex, a look up table may be used with the raw data. Thus, in some non-limiting embodiments, with linearization of sensor data and two or more position/force references, all forces within the range can be extrapolated.

In some embodiments, force thresholds can be set using architectural features that limit movement up to a certain force. For example, an element such as a spring, rubber element, or foam element can be by designed to be compressed during assembly to apply a pre-compression (e.g., 100 gf). In such cases, in order to be able to move it more, the system has to be compressed to more than 100 gf before moving again. In some embodiments, a hybrid detection method can be employed where the keyswitch (e.g., for a keyboard) or actuator (e.g., for a computer mouse) is triggered and can be validated via inductive sensing (e.g., detecting a force measurement). In some implementations, the force measurement can be used to enable analog sensing based on changes in the detected force measurement. Thus, galvanic mechanical switches can have key presses validated and/or supplemented with analog measurements via the embodiments described herein. For instance, rapid trigger detection can be employed with simple mechanical keyswitches using force detection by measuring increasing and decreasing force measurements and corresponding thresholds, as would be appreciated by one of ordinary skill in the art with the benefit of this disclosure. Conventional means of detecting force may employ FSRs, processors, and the like, which may take up considerable space on the substrate or secondary substrates, and can significantly and often prohibitively increase costs for the overall system. In some embodiments, a force-only keyed device is possible where no keyswitches or actuators are used, and only flexion of a substrate (e.g., PCB) is detected using the methods described herein to measure force. This can be used to provide analog detection and force detection (e.g., fast trigger), without requiring conventional, cost-prohibitive expensive components (e.g., FSRs) to achieve similar functional capabilities.

FIG. 5C-5D show various embodiments of a keyswitch mounted on a flexible PCB, according to certain embodiments. In FIG. 5C, a biasing element such as a spring or rubber element may be used between the substrate and bottom case (e.g., a portion of the housing) to help control the force/travel curve as the keyswitch is depressed. The biasing element can also provide a restoring force to return the substrate back to a neutral, non-flexed position. In some embodiments, a stopper can be used to set a hard limit to the downward force. In some embodiments, the target can be coupled to the metal plate (e.g., keyframe) or may be the metal plate itself.

In FIG. 5D, a biasing element such as a spring or rubber element may be used between the keyswitch and the metal plate. Rather than using a discrete stopper element, the keyswitch itself is limited in movement by the metal plate. In some embodiments, the target can be coupled to the metal plate (e.g., keyframe) or may be the metal plate itself.

FIG. 5E-5H show various embodiments of a keyswitch mounted on a flexible PCB, according to certain embodiment. In certain embodiments, the system can be designed so that the substrate only starts bending at a certain threshold force and can be limited to a certain range. For example, a biasing element (e.g., spring) can be preloaded to a certain force (e.g., 100 gF) and a stopper can be used to limit the range to 300 gF, as shown in FIGS. 5E-5H. Referring to FIG. 5E, the keyswitch is not pressed (0 gF is applied) and the substrate does not bend. In FIGS. 5F, 60 gF is applied and the keyswitch is activated (e.g., a key press event is instantiated). At this point, the substrate still remains unbent. In FIG. 5G, the downward force increases from 60 gF to below 100 gf. The keyswitch is already activated (when 60 gF was applied) and the substrate remains unbent. In FIG. 5H, at 100 gF the substrate begins to bend (thus enabling detection of an amount of travel of the substrate and a corresponding force detection) and continues to bend further as more force is applied and up to 300 gF where the stopper limits further travel of the substrate, as described above.

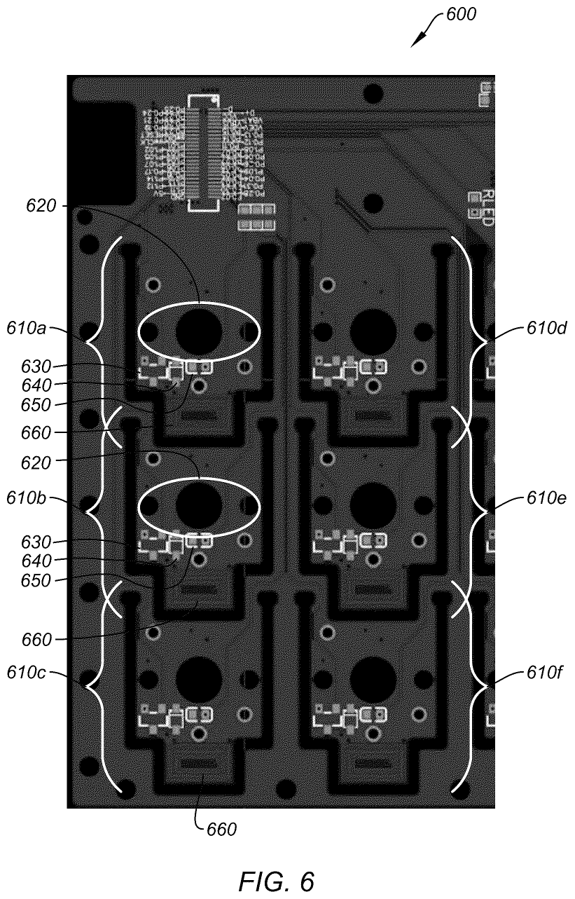

FIG. 6 shows a substrate 600 with an array mounting sites for keyswitches, according to certain embodiments. Substrate 600 can be a flexible substrate (e.g., a printed circuit board, as shown), such that when a downward force is applied, the substrate may flex (e.g., <1 mm), which may be measured and used to generate a force measurement, as described above. Substrate 600 can include a plurality of integrated keyswitch mounting blocks 610a-f, though more or fewer keyswitch mounting blocks may be used. Furthermore, although each keyswitch mounting block in FIG. 6 appears to be identical, keyswitch mounting blocks may differ from each other. For example, some keyswitch mounting blocks may be configured to receive a first type of keyswitch (e.g., galvanic) and some keyswitch mounting blocks may be configured to receive a second type of keyswitch (e.g., analog). In some cases, the keyswitch mounting blocks may be configured to receive a plurality of different types of keyswitches.

Keyswitch mounting block 610a can include a mounting socket 620 including one or more holes or sockets that are configured to receive corresponding mounting pins from a keyswitch. In some cases, keyswitch mounting block 620a can include a sensor 660 (e.g., inductive coil) that can be coupled to or integrated with substrate 600. In some embodiments, keyswitch mounting block 620a can include various electronics (e.g., discrete and/or embedded and/or integrated) such as transistor(s) 630 (e.g., operating as a current switch for controlling a current through sensor 660), capacitor(s) 650, diodes 640 (e.g., allow current to charge the capacitor(s), but not discharge into inductive coil 660), resistors, and the like, as would be appreciated by one of ordinary skill in the art with the benefit of this disclosure.

To allow for ample flexion (e.g., 0.1-1 mm), each keyswitch mounting block 610 (a-f) of substrate 600 may be unsupported along two or more edges within the substrate (e.g., by a compliant beam) to allow the keyswitch mounting block 610 to facilitate flexion of the substrate in a reliable and repeatable manner. Typically, increasing a number and/or length of unsupported edges will result in more flexion, however substrate thickness and material types can be contributing factors to flexibility as well. Referring to FIG. 6, each keyswitch mounting block is disconnected from surrounding substrate on three sides with sensor 360 configured on a portion that is subject to relatively more flexion than other locations on the keyswitch mounting block. It should be understood that the embodiment of FIG. 6 is but one non-limiting embodiment and different dimensions and substrate topologies are possible, as would be appreciated by one of ordinary skill in the art with the benefit of this disclosure.

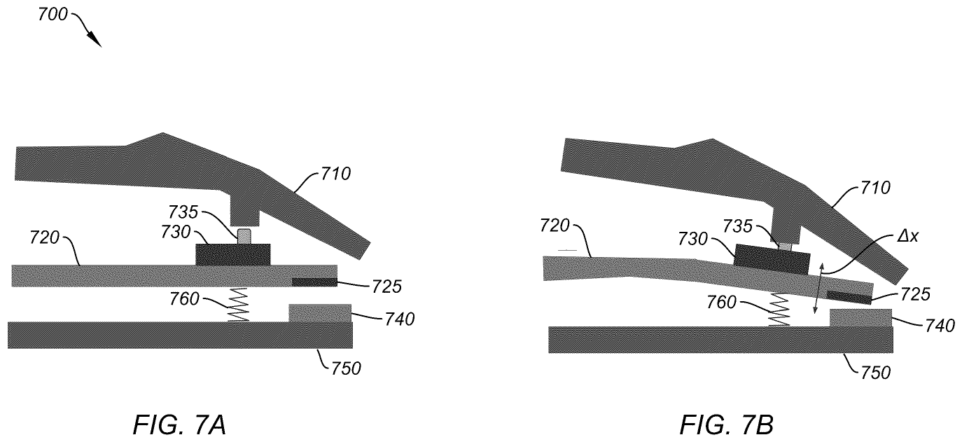

FIGS. 7A and 7B show a keypress sequence for a computer mouse with force detection, according to certain embodiments. A computer mouse 700 includes a keyplate 710, a flexible substrate 720, and a bottom case 750. A keyswitch 730 can be mounted on flexible substrate 720. When depressed (FIG. 7B), keyplate 710 or corresponding portion thereof can make contact with and activate keyswitch 730 (e.g., instantiate a key press event). Biasing mechanism 760 can be a spring (e.g., coil spring) that is operable to (1) provide a return force, causing keyplate 710 to return from a depressed state back to an unpressed state (FIG. 7A); and (2) set a preload threshold that prevents the substrate from flexing until a particular force is reached (e.g., 100 gf). Substrate 720 may include one or more sensors 725 (e.g., inductive coil). Bottom case 750 may include a target (e.g., ferromagnetic or paramagnetic), such as aluminum or other suitable material. In some cases, a second substrate may be used instead of bottom case 750.

In operation, force sensing in computer mouse 700 may operate similar to the keyed device 500 of FIGS. 5A-5B. For instance, sensor 725 can be operable to generate displacement data corresponding to a displacement between the sensor 725 and a target 740 on or of bottom case 750. As the distance (Δx) between the sensing element and target changes (e.g., moves closer together or farther apart), an amount of force applied to the corresponding keyswitch or button can be determined. In contrast to keyed device 500, as the substrate flexes, sensor 725 (e.g., inductive coil) and a target 740 (e.g., aluminum frame or element) move closer together rather than farther apart as shown in FIGS. 5A-5B, more eddy currents are induced in the target, a stronger second magnetic field is generated in the target, and thus the measured inductance of the inductive coil is decreased. The measured inductance can be correlated to a force measurement to determine an amount of force being applied to the substrate. In some cases, a stopper (e.g., typically comprised of foam or rubber) may be used to enable a small travel distance (e.g., <0.1 mm) that can be read by the sensor.

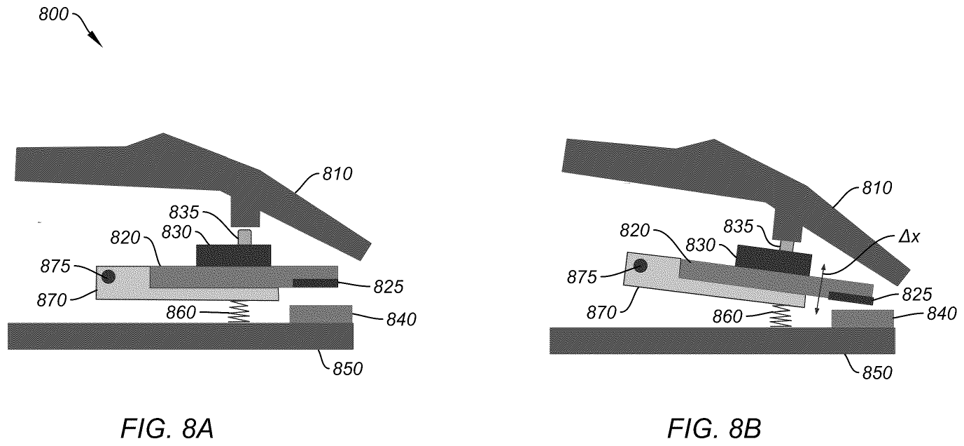

FIGS. 8A and 8B show a keypress sequence for a computer mouse 800 with force detection, according to some embodiments. Force detection in computer mouse 800 may be similar to that of computer mouse 700 where a distance (Δx) between a sensing element 825 and a target 840 changes (e.g., moves closer together or farther apart), and an amount of force applied to the corresponding keyswitch or button can be determined based on a measured inductance of the sensing element that changes based on said distance therebetween. However, rather than utilizing a flexible substrate, a fixed substrate 820 is coupled to a support structure 870 that rotates at a pivot point 875, as shown. When a sufficient force is applied to the system (e.g., 50 gf to trigger the actuator plus 10 gf or other suitable threshold force value), the support structure 870 may rotate/tilt as shown to enable a force measurement. In some aspects, biasing mechanism 860 may return the support structure from a rotated state (FIG. 8B) back to an unpressed state (FIG. 8A).

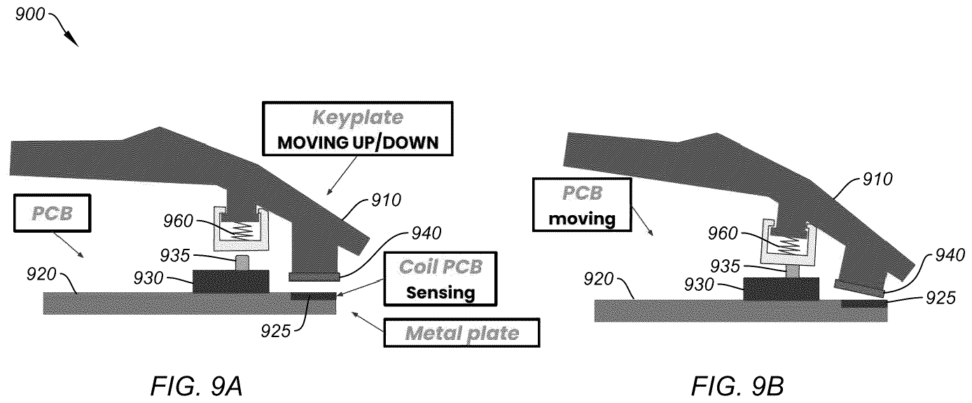

FIGS. 9A and 9B show a keypress sequence for a computer mouse 900 with force detection, according to some embodiments. Force detection in computer mouse 900 may be similar to that of computer mouse 700 where a distance (Δx) between a sensing element and a target changes (e.g., moves closer together or farther apart), and an amount of force applied to the corresponding keyswitch or button can be determined based on a measured inductance of the sensing element that changes based on the distance between them. Rather than the substrate bending, as shown in FIGS. 5A-7B, or the substrate rotating on a pivoting platform as shown in FIGS. 8A-8B, the keyplate itself may flex, causing a change in distance between the sensing element (e.g., configured on the substrate) and the target (e.g., coupled to a portion of the keyplate), as shown. One of ordinary skill in the art with the benefit of this disclosure would appreciate the many modifications, variations, and alternative embodiments thereof.

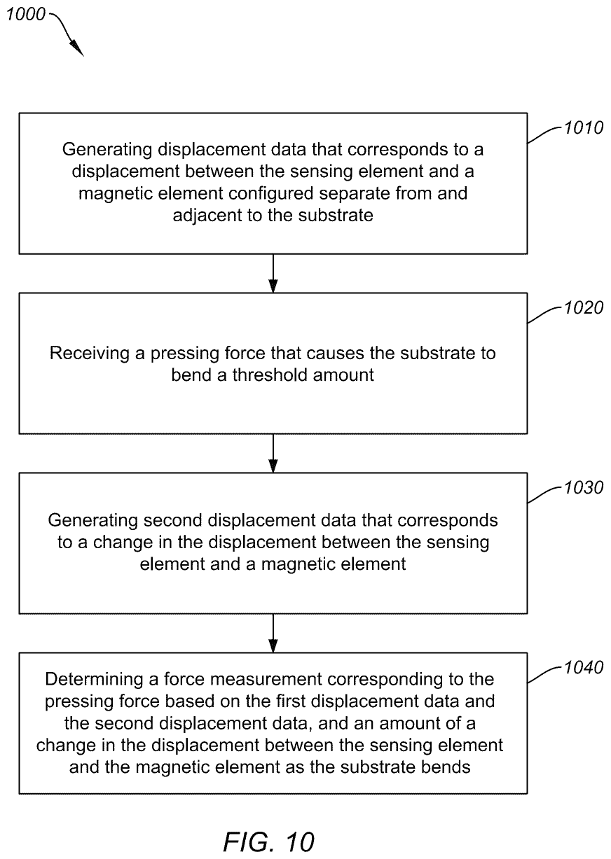

FIG. 10 is a simplified flow chart showing aspects of a method 1000 for force sensing on a keyed input device, according to certain embodiments. Method 1000 can be performed by processing logic that may comprise hardware (circuitry, dedicated logic, etc.), software operating on appropriate hardware (such as a general purpose computing system or a dedicated machine), firmware (embedded software), or any combination thereof. In certain embodiments, method 1000 can be performed by aspects of processor(s) 210, 302, or a combination thereof.

At operation 1010, method 1000 can include generating, by a sensing element 530 (e.g., inductive coil) configured on a substrate (e.g., printed circuit board) of the keyed device, displacement data that corresponds to a displacement between the sensing element and a target 540 (e.g., an electrically conductive element or material, such as a key frame) configured separate from and adjacent to the substrate, the substrate including a keyswitch 500 mounted thereon, according to certain embodiments.

At operation 1020, method 1000 can include receiving, by the keyswitch, a pressing force that causes the substrate to bend a threshold amount, according to certain embodiments.

At operation 1030, method 1000 can include generating, by the sensing element, second displacement data that corresponds to a change in the displacement between the sensing element and the target, according to certain embodiments. Typically, the sensing element moves as the substrate bends, and the target is typically immobile or substantially immobile (e.g., does not move more than 0.1 mm).

At operation 1040, method 1000 can include determining, by one or more processors, a force measurement corresponding to the pressing force based on the first displacement data and the second displacement data, and an amount of a change in the displacement between the sensing element and the target as the substrate bends, according to certain embodiments.

It should be appreciated that the specific steps illustrated in FIG. 10 provide a particular method 1000 for force sensing on a keyed input device, according to certain embodiments. Other sequences of steps may also be performed according to alternative embodiments. For instance, the sensing element is comprised of an inductive coil operable to generate a first magnetic field in response to an induced current, wherein the target generates a second magnetic field (e.g., due to eddy currents) in response to receiving the first magnetic field, the second magnetic field opposing the first magnetic field, wherein the one or more processors generates the force measurement, at least in part, by detecting an inductance of the inductive coil, and wherein the inductance of the inductive coil changes based on an amount of the second magnetic field received by the sensing element. In some cases, the keyed input device can include a frame, and the target can be directly or indirectly coupled to the frame, or may be the metal frame (electrically conductive material). In some aspects, the threshold force transferred from the keyswitch to the substrate is typically higher than a bottom-out force of the keyswitch (a force needed to cover the total travel of the switch), meaning that the force sensing is a secondary input that is enabled when the keyswitch is already fully depressed. In some embodiments, this can start around 60 gf (when the keyswitch is fully depressed) and continue until 300 gf (when a stopper is reached). In some embodiments, the threshold force transferred from the keyswitch to the substrate can be lower than the actuation force of the keyswitch (a force needed to make the switch click), meaning that the force sensing can be used as a side/additional input that can be used to improve the keyswitch detection stability (hybrid switch). For example, some embodiments may include force detection from 5 gf to 300 gf, or the like, such that force detection occurs while the keyswitch is being depressed. The moment at which the keyswitch clicks can also be used to dynamically calibrate the sensing element as this force is known. Furthermore, regarding method 1000, additional steps may be added or removed depending on the particular application. It should be noted that the embodiments described throughout this disclosure can be applied to any suitable input device including keyboards (e.g., keys), computer mice (e.g., buttons), or any other type of keyed input device. Any combination of changes can be used and one of ordinary skill in the art with the benefit of this disclosure would understand the many variations, modifications, and alternative embodiments thereof.

Most embodiments utilize at least one network that would be familiar to those skilled in the art for supporting communications using any of a variety of commercially available protocols, such as TCP/IP, UDP, OSI, FTP, UPnP, NFS, CIFS, and the like. The network can be, for example, a local area network, a wide-area network, a virtual private network, the Internet, an intranet, an extranet, a public switched telephone network, an infrared network, a wireless network, and any combination thereof.

In embodiments utilizing a network server as the operation server or the security server, the network server can run any of a variety of server or mid-tier applications, including HTTP servers, FTP servers, CGI servers, data servers, Java servers, and business application servers. The server(s) also may be capable of executing programs or scripts in response to requests from user devices, such as by executing one or more applications that may be implemented as one or more scripts or programs written in any programming language, including but not limited to Java®, C, C# or C++, or any scripting language, such as Perl, Python or TCL, as well as combinations thereof. The server(s) may also include database servers, including without limitation those commercially available from Oracle®, Microsoft®, Sybase®, and IBM®.

Such devices also can include a computer-readable storage media reader, a communications device (e.g., a modem, a network card (wireless or wired), an infrared communication device, etc.), and working memory as described above. The computer-readable storage media reader can be connected with, or configured to receive, a non-transitory computer-readable storage medium, representing remote, local, fixed, and/or removable storage devices as well as storage media for temporarily and/or more permanently containing, storing, transmitting, and retrieving computer-readable information. The system and various devices also typically will include a number of software applications, modules, services or other elements located within at least one working memory device, including an operating system and application programs, such as a client application or browser. It should be appreciated that alternate embodiments may have numerous variations from that described above. F or example, customized hardware might also be used and/or particular elements might be implemented in hardware, software (including portable software, such as applets) or both. Further, connections to other computing devices such as network input/output devices may be employed.

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure claimed subject matter. The various embodiments illustrated and described are provided merely as examples to illustrate various features of the claims. However, features shown and described with respect to any given embodiment are not necessarily limited to the associated embodiment and may be used or combined with other embodiments that are shown and described. Further, the claims are not intended to be limited by any one example embodiment.

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, it should be understood that the present disclosure has been presented for purposes of example rather than limitation, and does not preclude inclusion of such modifications, variations, and/or additions to the present subject matter as would be readily apparent to one of ordinary skill in the art. Indeed, the methods and systems described herein may be embodied in a variety of other forms; furthermore, various omissions, substitutions and changes in the form of the methods and systems described herein may be made without departing from the spirit of the present disclosure. The accompanying claims and their equivalents are intended to cover such forms or modifications as would fall within the scope and spirit of the present disclosure.

Although the present disclosure provides certain example embodiments and applications, other embodiments that are apparent to those of ordinary skill in the art, including embodiments which do not provide all of the features and advantages set forth herein, are also within the scope of this disclosure. Accordingly, the scope of the present disclosure is intended to be defined only by reference to the appended claims.

Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provide a result conditioned on one or more inputs. Suitable computing devices include multi-purpose microprocessor-based computer systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied—for example, blocks can be re-ordered, combined, and/or broken into sub-blocks. Certain blocks or processes can be performed in parallel.

Conditional language used herein, such as, among others, “can,” “could,” “might,” “may,” “e.g.,” and the like, unless specifically stated otherwise, or otherwise understood within the context as used, is generally intended to convey that certain examples include, while other examples do not include, certain features, elements, and/or steps. Thus, such conditional language is not generally intended to imply that features, elements and/or steps are in any way required for one or more examples or that one or more examples necessarily include logic for deciding, with or without author input or prompting, whether these features, elements and/or steps are included or are to be performed in any particular example.

The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Similarly, the use of “based at least in part on” is meant to be open and inclusive, in that a process, step, calculation, or other action “based at least in part on” one or more recited conditions or values may, in practice, be based on additional conditions or values beyond those recited. Headings, lists, and numbering included herein are for ease of explanation only and are not meant to be limiting.

The various features and processes described above may be used independently of one another or may be combined in various ways. All possible combinations and sub-combinations are intended to fall within the scope of the present disclosure. In addition, certain method or process blocks may be omitted in some embodiments. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed examples. Similarly, the example systems and components described herein may be configured differently than described. For example, elements may be added to, removed from, or rearranged compared to the disclosed examples.

What is claimed is:

1. A system for a keyed input device, the system comprising:
a substrate;
a keyswitch mounted on the substrate;
a target configured separate from and adjacent to the keyswitch and the substrate; and
a sensing element configured on the substrate, the sensing element operable to generate displacement data corresponding to a displacement between the sensing element and the target,
wherein the substrate is operable to bend in response to receiving a threshold force transferred from the keyswitch to the substrate, and
wherein a force measurement is generated based on the displacement data, the force measurement corresponding to an amount of a change in the displacement between the sensing element and the target as the substrate bends.

2. The system of claim 1 further comprising one or more processors,
wherein the sensing element is comprised of an inductive coil operable to generate a first magnetic field in response to an induced current,
wherein the target generates a second magnetic field in response to receiving the first magnetic field, the second magnetic field opposing the first magnetic field,
wherein the one or more processors generates the force measurement, at least in part, by detecting an inductance of the inductive coil, and
wherein the inductance of the inductive coil changes based on an amount of the second magnetic field received by the sensing element.

3. The system of claim 1 wherein the target is an electrically conductive material.

4. The system of claim 1 wherein the system includes a metal frame, and wherein the target is the metal frame.

5. The system of claim 1 wherein the threshold force transferred from the keyswitch to the substrate is higher than a bottom-out force of the keyswitch, such that a non-zero force measurement only occurs when the keyswitch is fully pressed.

6. The system of claim 1 wherein the substrate is configured to bend less than a threshold amount.

7. The system of claim 6 further comprising a stopper that prevents the substrate from bending more than the threshold amount.

8. The system of claim 7 wherein the threshold amount is less than 1 mm.

9. A force sensing system for a keyed input device, the force sensing system comprising:
a flexible substrate configured to bend in response to receiving a threshold force;
a target comprised of an electrically conductive material is configured separate from and adjacent to the substrate;
a sensing element configured on the substrate, the sensing element operable to generate displacement data corresponding to a displacement between the sensing element on the substrate and the target; and
one or more processors configured to:
receive the displacement data; and
generate a force measurement of a force imparted on the flexible substrate based on the displacement data, the force measurement corresponding to an amount of a change in the displacement between the sensing element and the target as the substrate bends.

10. The force sensing system of claim 9 wherein the target is immobile.

11. The force sensing system of claim 9 wherein the sensing element is comprised of an inductive coil operable to generate a first magnetic field in response to an induced current,
wherein the target generates a second magnetic field in response to receiving the first magnetic field, the second magnetic field opposing the first magnetic field,
wherein the one or more processors generates the force measurement, at least in part, by detecting an inductance of the inductive coil, and
wherein the inductance of the inductive coil changes based on an amount of the second magnetic field received by the sensing element.

12. The force sensing system of claim 9 wherein the system includes a frame, and wherein the target is coupled to the frame or is the frame.

13. A method of operating a keyed device, the method comprising:
generating, by a sensing element configured on a substrate of the keyed device, first displacement data that corresponds to a displacement between the sensing element and a target configured separate from and adjacent to the substrate, the substrate including a keyswitch mounted thereon;
receiving, by the keyswitch, a pressing force that causes the substrate to bend a threshold amount;
generating, by the sensing element, second displacement data that corresponds to a change in the displacement between the sensing element and a target; and
determining, by one or more processors, a force measurement corresponding to the pressing force based on the first displacement data and the second displacement data, and an amount of a change in the displacement between the sensing element and the target as the substrate bends.

14. The method of claim 13 wherein the sensing element is comprised of an inductive coil operable to generate a first magnetic field in response to an induced current,
wherein the target generates a second magnetic field in response to receiving the first magnetic field, the second magnetic field opposing the first magnetic field,
wherein the one or more processors generates the force measurement, at least in part, by detecting an inductance of the inductive coil, and
wherein the inductance of the inductive coil changes based on an amount of the second magnetic field received by the sensing element.

15. The method of claim 13 wherein the keyed device includes a frame, and wherein the target is coupled to the frame or the target is the frame.

16. A computer mouse comprising:
a housing;
a keyplate coupled to the housing, the keyplate configured to be depressed along a range of motion;
a first substrate disposed in the housing;
a keyswitch mounted on the first substrate, the keyplate configured activate the keyswitch when the keyplate is depressed a threshold distance;
a sensing element coupled to the first substrate;
a second substrate coupled to the housing; and
a target mounted on the second substrate,
the sensing element operable to generate displacement data corresponding to a displacement between the sensing element and the target,
wherein the first substrate is operable to bend in response to receiving a threshold force transferred from the keyswitch to the first substrate when the keyplate is depressed, and
wherein a force measurement is generated based on the displacement data, the force measurement corresponding to an amount of a change in the displacement between the sensing element and the target as the substrate bends.

17. The computer mouse of claim 16 wherein the second substrate is part of or is integrated with a portion of the housing.

18. The computer mouse of claim 16 further comprising one or more processors,
wherein the sensing element is comprised of an inductive coil operable to generate a first magnetic field in response to an induced current,
wherein the target generates a second magnetic field in response to receiving the first magnetic field, the second magnetic field opposing the first magnetic field,
wherein the one or more processors generates the force measurement, at least in part, by detecting an inductance of the inductive coil, and
wherein the inductance of the inductive coil changes based on an amount of the second magnetic field received by the sensing element.

19. The computer mouse of claim 16 wherein the threshold force transferred from the keyswitch to the first substrate is higher than a bottom-out force of the keyswitch, such that a non-zero force measurement only occurs when the keyswitch is fully pressed.

20. The computer mouse of claim 16 wherein the threshold force transferred from the keyswitch is lower than an actuation force of the keyswitch, wherein the force measurement is used to confirm a keypress event.
